(19) United States
(12) Patent Application Publication
(10) Pub. No.: US 2025/0309196 A1
(43) Pub. Date: Oct. 2, 2025

(54) EMBEDDED ALIGNED FIDUCIAL MARKERS FOR STACKED FANOUT SEMICONDUCTOR DEVICE

(71) Applicant: Western Digital Technologies, Inc., San Jose, CA (US)

(72) Inventors: Cong Zhang, Shanghai (CN); Xuyi Yang, Shanghai (CN); Cheng-Hsiung Yang, Taichung (TW); Pradeep Rai, Milpitas, CA (US); Nagesh Vodrahalli, Los Altos, CA (US)

(73) Assignee: Western Digital Technologies, Inc., San Jose, CA (US)

(21) Appl. No.: 18/621,497

(22) Filed: Mar. 29, 2024

(51) Int. Cl. H01L 25/065; H01L 23/00; H01L 23/31; H01L 23/544

(52) U.S. Cl. CPC H01L 25/0657; H01L 23/3121; H01L 23/544; H01L 24/48; H01L 24/94; H01L 2223/54426; H01L 2224/48145; H01L 2224/94; H01L 2225/06506; H01L 2225/06562; H01L 2924/1438

(57) ABSTRACT

A fanout semiconductor package includes a first mold compound encapsulating a group of semiconductor dies, and a second mold compound encapsulating the first mold compound. A first set of one or more fiducial markers are included within the first mold compound for aligning the semiconductor dies in the first mold compound. A second set of one or more fiducial markers are included outside of the first mold compound and inside the second mold compound for aligning the semiconductor dies in the second mold compound. Passive components may also be mounted outside of the first mold compound and inside the second mold compound.

### BACKGROUND

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While many varied packaging configurations are known, flash memory storage cards may in general be fabricated as system-in-a-package (SiP) or multichip modules (MCM), where a plurality of die are mounted and interconnected on a small footprint substrate. The substrate may in general include a rigid, dielectric base having a conductive layer etched on one or both sides. Electrical connections are formed between the die and the conductive layer(s), and the conductive layer(s) provide an electric lead structure for connection of the die to a host device. Once electrical connections between the die and substrate are made, the assembly is then typically encased in a mold compound which provides a protective package.

One type of semiconductor package is a so-called fanout chip-scale package, where a semiconductor die is embedded in a mold compound. Electrical connections are made from the die to a surface of the mold compound. Thereafter, a redistribution layer (RDL) may be affixed to the surface of the mold compound electrically coupling and redistributing the electrical connections at the surface of the mold compound to solder balls on an opposed surface of the RDL.

Fanout packages have an advantage in that they have a small footprint, often generally the size of the semiconductor dies themselves. However, fanout packages are difficult to manufacture. One problem is the difficulty in aligning semiconductor the semiconductor dies within the package to the RDL on a surface of the package. Another difficulty is how provide passive components, which have no connection to the surface of the mold compound.

### DESCRIPTION OF THE DRAWINGS

FIG. 1 is a flowchart for the assembly of a semiconductor device according to embodiments of the present technology.

FIG. 2 illustrates a first temporary carrier according to embodiments of the present technology.

FIG. 3 illustrates fiducial marks formed on the carrier according to embodiments of the present technology.

FIG. 4 is an edge view of a fanout package formed on the carrier according to embodiments of the present technology.

FIG. 5 is a perspective view of the fanout package formed on the carrier according to embodiments of the present technology.

FIG. 6 is an edge view of the fanout package encapsulated in mold compound according to embodiments of the present technology.

FIG. 7 is an edge view of the encapsulated fanout package after grinding according to embodiments of the present technology.

FIG. 8 is an edge view showing removal of the carrier from the fanout package according to embodiments of the present technology.

FIG. 9 shows a top view of a number of encapsulated panels of fanout packages mounted on a wafer according to embodiments of the present technology.

FIG. 10 shows a top view of the panels of FIG. 9 after singulation according to embodiments of the present technology.

FIG. 11 is an edge view of the singulated fanout packages being mounted on a second temporary carrier according to embodiments of the present technology.

FIG. 12 is an edge view of fanout packages on the second carrier encapsulated in a second mold compound according to embodiments of the present technology.

FIG. 13 is an edge view showing removal of the second carrier from the block of fanout packages encapsulated in the second mold compound according to embodiments of the present technology.

FIG. 14 shows an RDL and ball bump on an active surface of the encapsulated fanout packages according to embodiments of the present technology.

FIG. 15 shows diced fanout packages according to embodiments of the present technology.

### DETAILED DESCRIPTION

The present technology will now be described with reference to the figures, which in embodiments, relate to a fanout semiconductor device. The device including a plurality of semiconductor dies is initially constructed on a first temporary carrier. Fiducial markers are formed on the first temporary carrier to facilitate alignment of the semiconductor dies on the first carrier. The plurality of semiconductor dies are encapsulated in mold compound, and the mold compound is subsequently thinned in a grinding process to expose electrical connections from the dies at the surface of the mold compound. The first temporary carrier is then removed and the individual fanout packages are singulated.

The fanout packages then undergo a subsequent construction on a second temporary carrier, referred to herein as a reconstruction process. The second temporary carrier includes passive devices as well as a second set of fiducial markers. The fanout packages are mounted on the second temporary carrier with the active surface of the fanout packages facing the second temporary carrier. The first and second sets of fiducial markers are used to align the fanout packages on the second temporary carrier. The fanout packages undergo a second encapsulation process and the second temporary carrier is subsequently removed. A redistribution layer (RDL) is then constructed on the exposed active surface of the encapsulated fanout packages, electrically coupling and redistributing the electrical connections at the active surface of the fanout packages to solder balls on an opposed surface of the RDL. The respective fanout packages may then be singulated from the second molding compound.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal” as may be used herein are by way of example and illustrative purposes only, and are not meant to limit the description of the invention inasmuch as the referenced item can be exchanged in position and orientation. Also, as used herein, the terms “substantially,” “approximately” and/or “about” mean that the specified dimension or parameter may be varied within an acceptable manufacturing tolerance for a given application. In one embodiment, the acceptable manufacturing tolerance is +0.15 mm, or alternatively, +2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

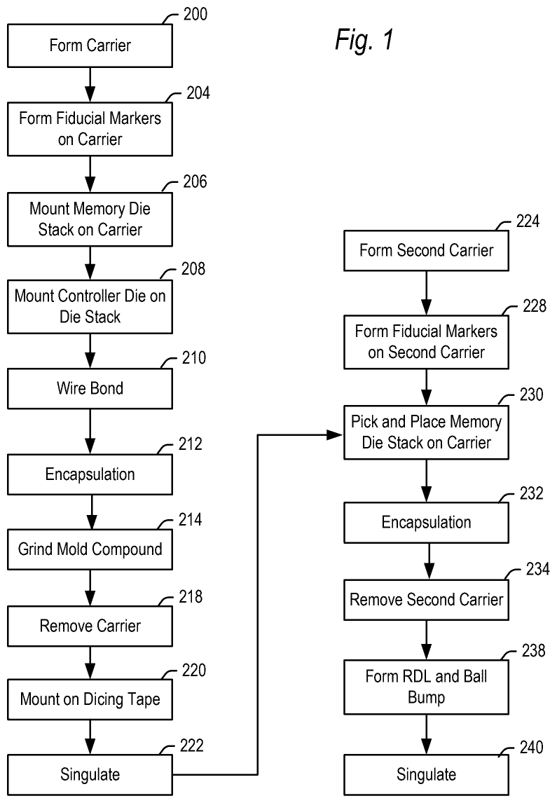

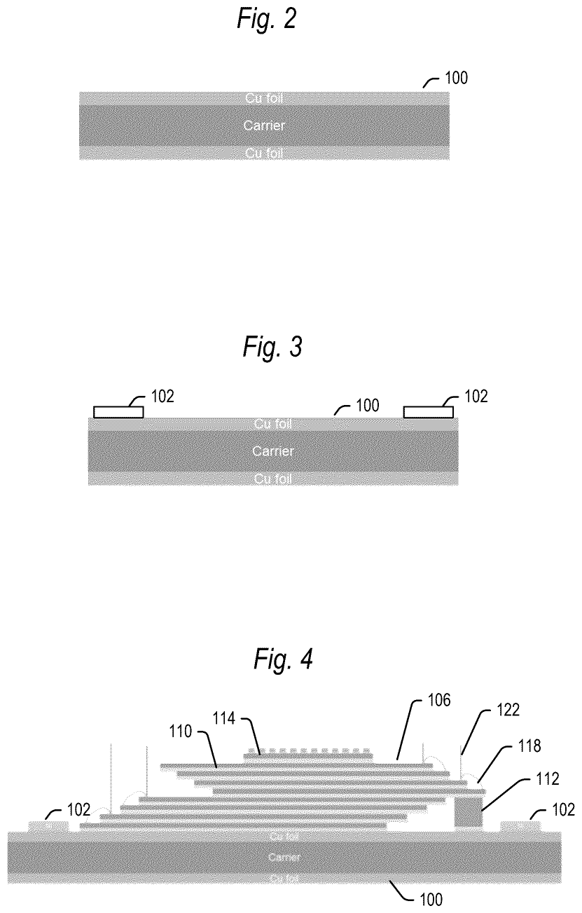

An embodiment of the present invention will now be explained with reference to the flowchart of FIG. 1 and the partial perspective and edge views of FIGS. 2 through 18. FIGS. 4 through 8 each show an individual semiconductor package 136, or a portion thereof. However, as explained below, the packages 136 may be batch processed along with a plurality of other packages on a carrier to achieve economies of scale. The number of rows and columns of package 136 on the carrier may vary.

Referring now to the flowchart of FIG. 1 and the views of FIGS. 2-8, fabrication of a semiconductor package 136 may begin in step 200 with forming a first temporary carrier 100. The carrier 100 may have a pair of copper foil layers on respective surfaces of a base layer. The base layer may for example be formed of a metal or dielectric material, though it may be formed of other materials in further embodiments. In one example, the top foil layer may be affixed to the first temporary carrier 100 using a temporary bonding film.

In step 202, fiducial markers 104 may be formed on a copper foil by lithography and plating on the top surface of the first temporary carrier 100. The fiducial markers 104 may be formed of nickel or other metals in further embodiments, and may also be formed of solder mask or other organic materials that can be distinguished from the molding compound as explained below. The markers may be plated to include shapes or patterns, such as circles, crosses, squares or right angles that can be sensed as explained below to, for example, align dies on the surface of the carrier 100. The markers 104 are located in predetermined positions on the carrier 100, near the locations where the semiconductor dies will be attached as explained below.

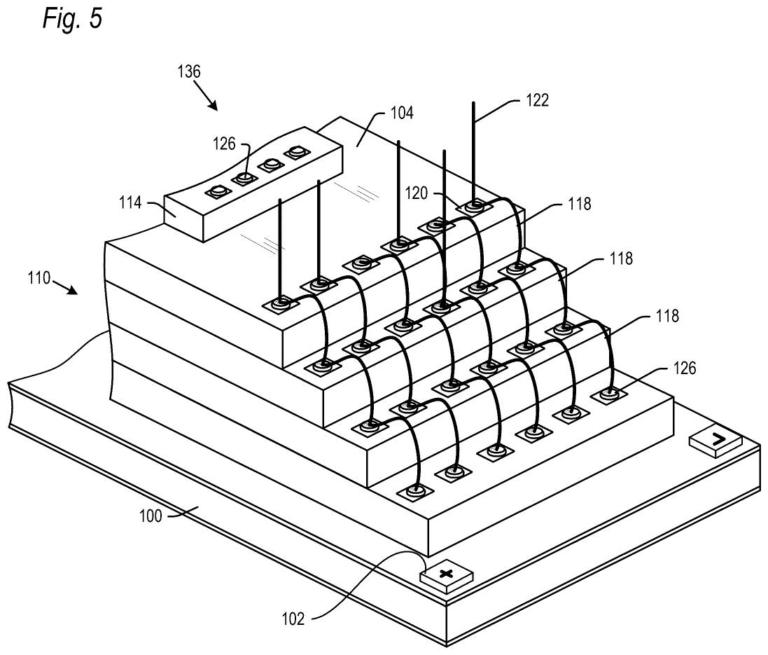

In step 206, a plurality of semiconductor dies 106 are stacked on the carrier 100 as shown in the edge view of FIG. 4 and the perspective view of FIG. 5. The semiconductor dies 106 may for example be memory dies such a NAND flash memory die, but other types of die 106 may be used. The memory dies may be so-called CMOS bonded array (CBA) module including a memory die bonded to a CMOS logic circuit die. The semiconductor dies 106 may be stacked atop each other in an offset (FIG. 5), or double offset (FIG. 4), stepped configuration to form a die stack 110. The double offset configuration of FIG. 4 may comprise a spacer block 112 to support the upper dies 106 during wire bond and encapsulation as explained below. The spacer block may be omitted in further embodiments.

In the example shown, the semiconductor package 136 includes eight semiconductor die 106. However, the die stack 110 may include more or less than eight semiconductor die in further embodiments, including for example 2, 4, 16 and 32 semiconductor die. The die 106 may be affixed to each other in the stack 110 using a DAF (die attach film). As one example, the DAF may be 8988UV epoxy from Henkel Corp of California, USA.

One function of the one or more fiducial markers 104 is to precisely align and define positions of each of the dies 106 on the carrier 100. In particular, the fiducial markers 104 act as reference points by which dies are formed on the carrier 100 in their respective stacks. As the die are placed on the carrier 100, the pick and place robot or other assembly equipment may include vision systems or alignment sensors that can detect the fiducial markers and precisely align the die in predetermined positions on the carrier, for example aligning a reference point on each die 106 (e.g., a corner of the die) a predetermined distance in an x, y coordinate plane from the fiducial markers 104. This allows precise positioning of the dies 106 in the stack 110. In embodiments, precise placement of the dies is important to achieving proper electrical connections and optimal performance in the final packaged semiconductor device.

In embodiments, a controller die 114 may be mounted on top of the die stack 110 in step 208. The controller die 114 may be an ASIC for controlling flow of data and signals to/from the die stack 110. In further embodiments, the controller die 114 may be mounted beneath the die stack 110.

Once the die stack 110 and controller die 114 are mounted on the carrier 100, the respective dies 106 and 114 may be electrically connected to each other in step 210 using bond wires 118. FIGS. 4 and 5 show simplified edge and perspective views with a few bond wires shown for illustration purposes. There may be many more bond wires 118 than shown. Each semiconductor die 106 may include a row of die bond pads 120 along one or both edges of the dies 106. It is understood that each die 106 may include many more die bond pads 120 than is shown in FIG. 5. Each die bond pad 120 in the row of a semiconductor die may be electrically connected to the corresponding die bond pad 120 in the row of the next adjacent semiconductor die using a bond wire 118 formed as described below.

In order to form bond wires 118, in embodiments, a stud bump 126 may initially be deposited on each of the die bond pads 120. After the stud bumps 126 are deposited on the bond pads 120, stitch wire bonds 118 may be formed on the stud bumps 126 on a die 106 (for example on the bottom die 106) up to the corresponding stud bumps 126 on the next higher die (for example the second die 106 from the bottom). This process may be repeated up the die stack 110 until bond wires 118 are formed between all corresponding die bond pads 120 in a column of die bond pads in stack 110.

In order to form the fanout package of the present technology, electrical connections outside of the package will be made upward from the die stack. As such, the die stack 110 may further include vertical bond wires 122 used for external electrical connections as explained below. The vertical bond wires 122 shown in FIGS. 4 and 5 are by way of example only, and there may be more or less vertical bond wires 122 in further embodiments.

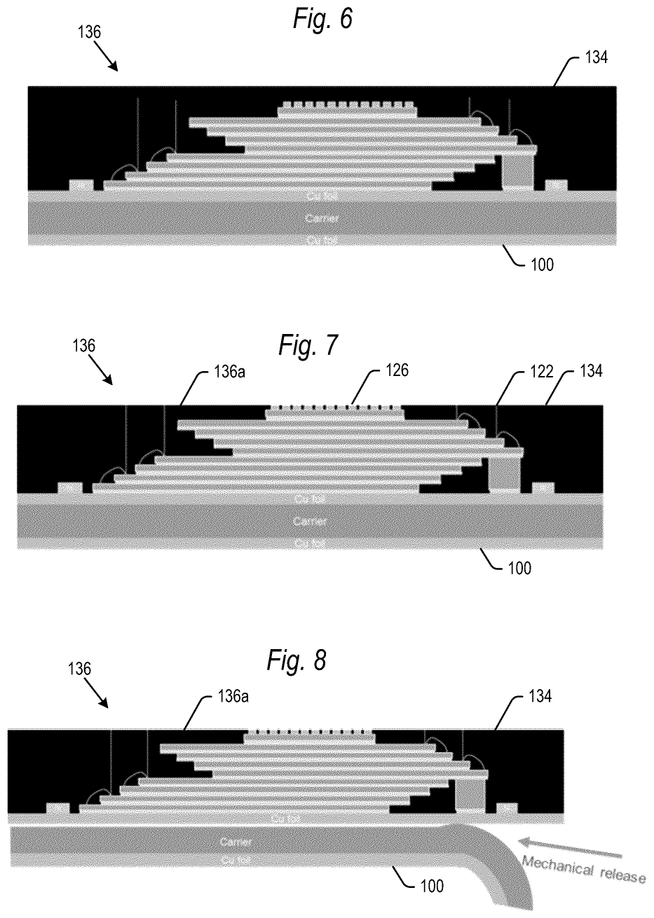

After the electrical connections are formed, the die stack 110 may be encapsulated in a mold compound 134 in step 212 and as shown in FIGS. 6-8. The mold compound may be applied onto the surface of the carrier 100, surrounding the semiconductor dies 106 and 114, as well as the bond wires 118 and 122. Mold compound 134 may include for example solid epoxy resin, Phenol resin, fused silica, crystalline silica, carbon black and/or metal hydroxide. Such mold compounds are available for example from Sumitomo Corp. and Nitto-Denko Corp., both having headquarters in Japan. Other mold compounds from other manufacturers are contemplated. The mold compound may be applied according to various known processes, including by FFT (flow free thin) molding, transfer molding or injection molding techniques.

At this stage, the respective fanout packages 136 are defined within the mold compound 134. As shown in the figures, the overall footprint (length and width) of a semiconductor die 106, and also the die stack 110, is slightly smaller than a footprint of the mold compound 134 in fanout package 136. As explained below, an RDL pad may be affixed to the mold compound, which may have the same footprint as the surface of the mold compound to which it is attached. As noted above and explained below, multiple semiconductor packages 136 may be formed on the first temporary carrier 100. The mold compound may be applied across the entire surface of the rigid carrier 100, forming a block of mold compound encapsulating all of the packages 136 on the carrier 100.

In step 214, a grinding process may be performed at a top surface of the mold compound 134 as shown in FIG. 7. The grinding process exposes the vertical bond wires 122, and also exposes the stud bumps 126 on top of controller die 114. The surface of the mold compound 134 for each fanout package 136 including the exposed electrical connections is referred to herein as the active surface 136a of the fanout packages 136 and mold compound 134. In step 218, the carrier 100 may be removed as shown in FIG. 8. The carrier may for example be heated to liquify the temporary bonding film between the upper foil layer and the dielectric layer to allow removal of the dielectric layer and bottom foil layer, while the top foil layer remains intact. Thereafter, a chemical wet etch may be performed to remove the top foil layer, as well as any particulates from the grinding step 214. Besides chemical wet etch, mechanical grinding may also be used to remove the top foil layers.

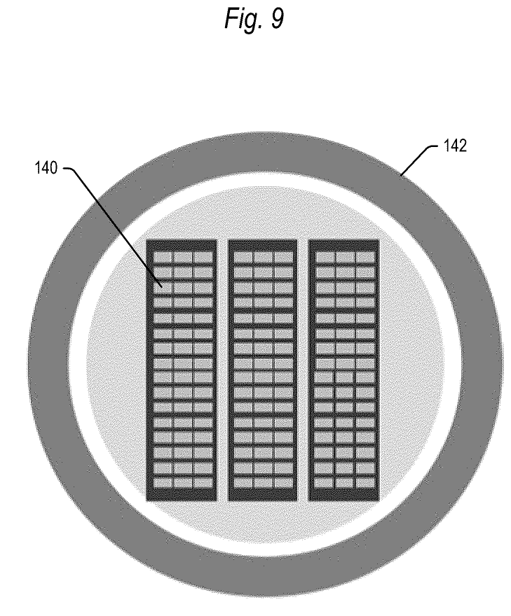

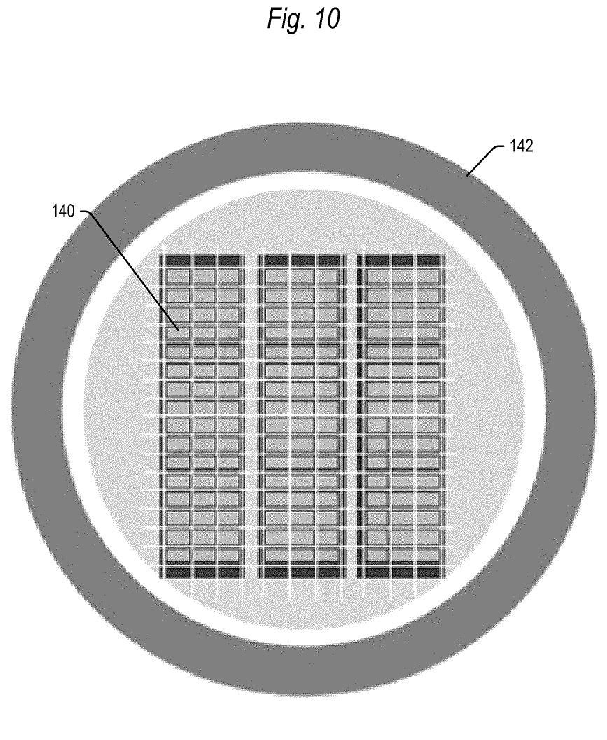

As noted, the encapsulated packages 136 may be formed on a panel. After removal of the carrier in step 218, one or more of these panel 140 may be mounted on a dicing tape on a wafer ring 142 in step 220 and as shown in FIG. 9. In step 222, the individual packages 136 may be singulated from the panels 140 as shown in FIG. 10. The individual packages 136 may be singulated by a variety of methods including saw blade, laser and water jet.

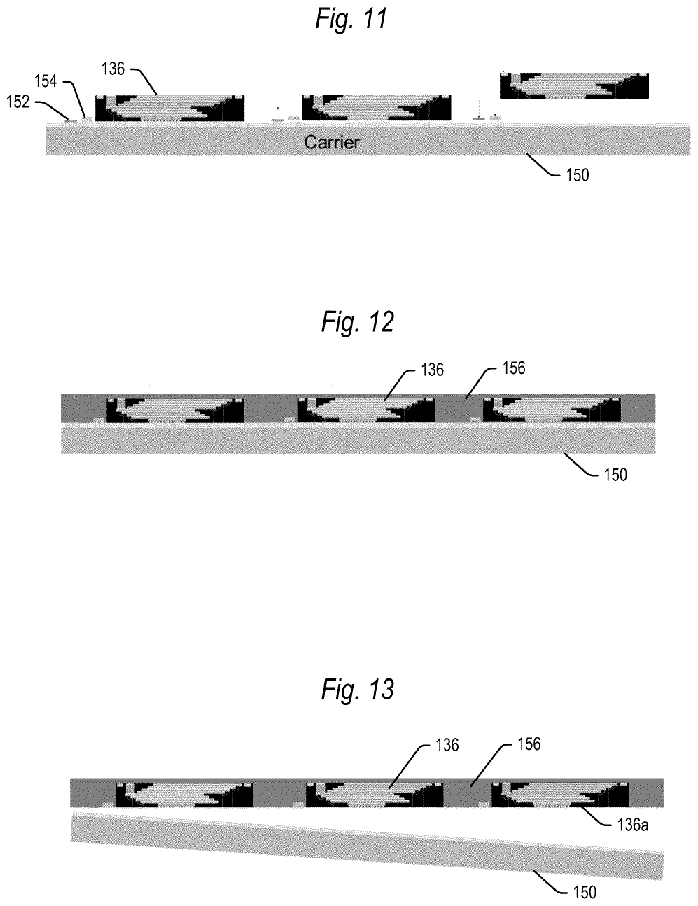

Before, during or after formation of the diced semiconductor packages 136, a second carrier 150 may be formed as shown in FIG. 11. A second set of fiducial markers 152 may be mounted on the second carrier 150 in step 228. The second set of fiducial markers 152 may be formed in the same way and of the same materials as the markers 104. The fanout package 136 uses a variety of passive components 154 including for example resistors, capacitors and inductors. In conventional semiconductor packages, these passive components may be mounted on the substrate, and electrically connected downward to the substrate with external connections through a bottom of the substrate. However, in the fanout package 136, electrical connections are made upward. Therefore, passive components 154 are also mounted on the carrier 150 for external electrical connection as explained below.

Referring now to steps 230 to 240, the singulated fanout packages 136 may next be reconstructed onto the second temporary carrier 150. In step 230, a pick and place robot may be used to transfer the semiconductor packages 136 from the wafer 142 to the second carrier 150 as shown in FIG. 11. The packages 136 are positioned on the second carrier 150 with the active surfaces 136a of the packages 136 facing against the carrier 150. All being mounted on the second temporary carrier 150, the active surface 136a, the one or more passive components and the second set of one or more fiducial markers are all coplanar with each other.

One function of the second set of one or more fiducial markers 152 is to precisely align and define positions of each of the packages 146 on the carrier 150. In particular, the fiducial markers 152 act as reference points by which the packages 136 are mounted on the carrier 150. The first set of fiducial markers 102 remain exposed in top (inactive) surfaces of the packages 136. As the packages 136 are placed on the carrier 150, the pick and place robot or other assembly equipment may include vision systems or alignment sensors that can detect the first and second sets of fiducial markers 104, 152 and precisely align the packages 136 in predetermined positions on the carrier 150. In embodiments, precise placement of the packages 136 on carrier 150 is important to achieving proper electrical connections and optimal performance in the final packaged semiconductor device.

After the packages 136 are mounted on the carrier 150, the packages 136, fiducial markers 152 and passive components 154 may be encapsulated in a second mold compound 156 in step 232 and as shown in FIG. 12. As above, the second mold compound 156 may be applied according to various known processes, including by FFT (flow free thin) molding, transfer molding or injection molding techniques. The second mold compound 156 may be the same as the first mold compound 134. The second mold compound may be different than the first mold compound 134, but in embodiments, it may have the same coefficient of thermal expansion. The second mold compound may be higher thermal conductivity to enhance heat removal performance, as second mold compound does not have an issue with filling and flowability in certain configurations (e.g., no wires, no tunnels to fill, etc.). After hardening of the second mold compound 156, the second carrier 150 may be removed in step 234 and as shown in FIG. 13. Removal of the second carrier 150 exposes the active surfaces 136a of each package 136 including the ends of vertical bond wires 122 and the exposed stud bumps 126.

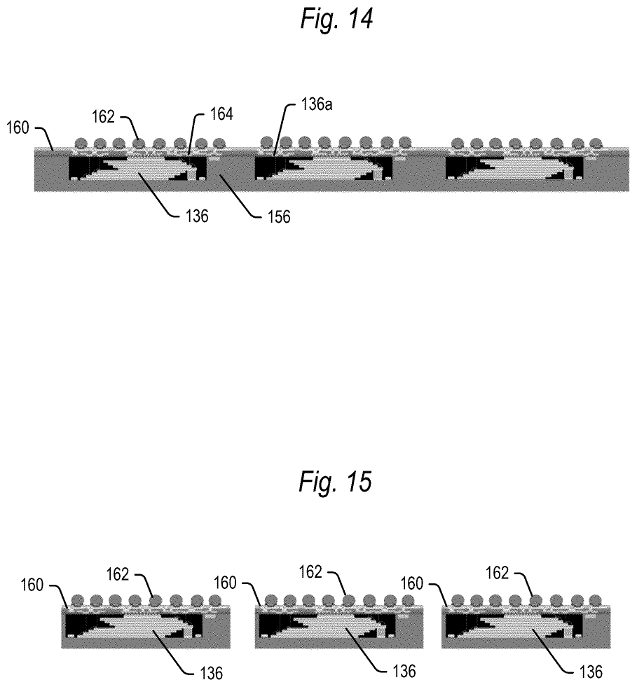

In step 238, an RDL 160 and solder ball bumps 162 may be formed on the active surface 136a of packages 136 as shown in FIG. 14. The RDL 160 includes a first surface having an adhesive to affix the RDL 160 directly to the surface 136a and mold compound 156. The first surface of the RDL 160 includes a number of contact pads 164 having positions and a configuration to mate with the exposed vertical bond wires 122 and the stud bumps 126 exposed at the surface 136a. The ability to match the positions of contact pads 164 to the vertical bond wires 122 and stud bumps 126 is facilitated by the second set of fiducial markers 152.

The RDL 160 includes an electrical conductance pattern formed of a number of electrical traces and vias which electrically couple (effectively, redistributing) the vertical bond wires 122 and stud bumps 126 with select ones of the solder balls 162. It is understood that the pattern of solder balls 162, electrical traces and vias are shown by way of example only, and the RDL 160 may include other patterns of solder balls 162, traces and vias in further embodiments.

In step 240, the individual semiconductor packages 136 may be singulated from the block of mold compound 156 to result in the finished encapsulated semiconductor packages 136. The packages may be singulated by methods including saw blade, laser and water jet. The vertical bond wires 122, stud bumps 126 and RDL 160 electrically couple the die bond pads on the dies 106 to select ones of solder balls 162 to enable communication between the semiconductor package 136 and a host device on which the package 136 is mounted (not shown). The host device may for example be a printed circuit board. The package 136 may be physically and electrically coupled to the host device by the solder balls 162 which may be hardened in a reflow process to permanently affix the package 136 to the host device.

The present technology provides a number of advantages. For example, by using the reconstruction process, only known good packages 136 may be selected for placement on the second carrier 150 and connected by RDL 160. This ensures that a yield rate at or near 100%. Conventionally, if any die stack were faulty, it was still covered in RDL resulting in waste. Second, by mounting the passive components in the reconstruction process, these components may be electrically coupled to the RDL. As noted above, this was not possible with conventional fanout packages. Third, reconstructing the packages on the second temporary carrier allows the second temporary carrier to be customized to any of a variety of sizes, including non-standard sizes. This allows the reconstructed packages to be customized for, and processed on, existing assembly fab equipment, and minimizes the need to change equipment within an assembly fab to construct the finished fanout packages. As another advantage, the present technology allows for flexible and variable panel size, which can adapt to any existing process, thereby reducing the threshold for entering the fanout market.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor package, comprising:
a plurality of stacked semiconductor dies;
electrical connectors configured to transfer signals to and from the plurality of stacked semiconductor dies;
a first set of one or more fiducial markers configured to align the semiconductor dies in the plurality of stacked semiconductor dies;
a first mold compound, the plurality of semiconductor dies and first set of one or more fiducial markers encapsulated within the first mold compound so that ends of the electrical connectors are exposed at an active surface of the first mold compound;
a second set of one or more fiducial markers;
a second mold compound encapsulating the first mold compound and the second set of one or more fiducial markers;
a redistribution layer (RDL) mounted on the active surface and configured to redistribute the electrical connectors from the plurality of semiconductor dies, wherein the second set of one or more fiducial markers is configured to align contact pads in the RDL with the electrical connectors in the active surface.

2. The semiconductor package of claim 1, wherein the electrical connectors comprise a plurality of bond wires electrically coupled between the plurality of semiconductor dies.

3. The semiconductor package of claim 1, wherein the electrical connectors comprise a plurality of bond wires having first ends electrically coupled to the plurality of semiconductor dies and second ends extending away from surfaces of the plurality of semiconductor dies to which the first ends are attached.

4. The semiconductor package of claim 3, wherein the second ends of the electrical connectors comprise the ends of the electrical connectors exposed at the active surface of the first mold compound.

5. The semiconductor package of claim 1, further comprising a controller die mounted atop the die stack, the controller die comprising electrical connections exposed at the active surface of the first mold compound.

6. The semiconductor package of claim 5, the electrical connectors further comprising wire bonds between the controller die and one or more semiconductor dies of the plurality of semiconductor dies.

7. The semiconductor package of claim 5, further comprising solder balls on the RDL, and wherein the RDL electrically couples and redistributes electrical connectors from the plurality of semiconductor dies and the electrical connections from the controller die to the solder balls.

8. The semiconductor package of claim 1, wherein surfaces of the first set of one or more fiducial markers are coplanar with a surface of a bottommost semiconductor die in the plurality of stacked semiconductor dies.

9. The semiconductor package of claim 1, further comprising one or more passive components mounted outside the first mold compound and inside the second mold compound.

10. The semiconductor package of claim 8, wherein the one or more passive components are mounted in a plane of the active surface.

11. The semiconductor package of claim 9, further comprising solder balls on the RDL, and wherein the RDL electrically couples the one or more passive components to the solder balls.

12. The semiconductor package of claim 1, wherein the plurality of stacked semiconductor dies comprise NAND flash memory dies.

13. The semiconductor package of claim 1, wherein the plurality of stacked semiconductor dies comprise CMOS bonded array semiconductor dies.

14. A semiconductor package, comprising:
a plurality of stacked semiconductor dies;
electrical connectors configured to transfer signals to and from the plurality of stacked semiconductor dies;
a first mold compound encapsulating the plurality of stacked semiconductor dies so that ends of the electrical connectors are exposed at an active surface of the first mold compound;
a second mold compound encapsulating the first mold compound and leaving the active surface of the first mold compound exposed;
one or more passive components mounted outside of the first mold compound and inside the second mold compound; and
a redistribution layer (RDL) mounted on the active surface and configured to redistribute the electrical connectors from the plurality of semiconductor dies.

15. The semiconductor package of claim 14, further comprising a first set of one or more fiducial markers inside the first mold compound, the first set of one or more fiducial markers configured to align the semiconductor dies in the plurality of stacked semiconductor dies.

16. The semiconductor package of claim 14, further comprising a second set of one or more fiducial markers outside of the first mold compound and inside the second mold compound, the second set of one or more fiducial markers is configured to align contact pads in the RDL with the electrical connectors in the active surface.

17. The semiconductor package of claim 14, wherein the electrical connectors comprise a first plurality of bond wires electrically coupled between the plurality of semiconductor dies, and a second plurality of bond wires having first ends electrically coupled to the plurality of semiconductor dies and second ends terminating at the active surface of the first mold compound.

18. The semiconductor package of claim 14, further comprising a controller die mounted atop the die stack, the controller die comprising electrical connections exposed at the active surface of the first mold compound.

19. The semiconductor package of claim 14, further comprising solder balls on the RDL, and wherein the RDL electrically couples the one or more passive components to the solder balls.

20. A semiconductor package, comprising:
a plurality of stacked semiconductor dies;
electrical connectors configured to transfer signals to and from the plurality of stacked semiconductor dies;
a first mold compound encapsulating the plurality of semiconductor dies so that ends of the electrical connectors are exposed at an active surface of the first mold compound;
a second mold compound encapsulating the first mold compound and leaving the active surface of the first mold compound exposed;
first alignment means inside the first mold compound for aligning the semiconductor dies in the plurality of stacked semiconductor dies;
second alignment means outside of the first mold compound and inside the second mold compound for aligning the plurality of stacked semiconductor dies within the second mold compound; and
a redistribution layer (RDL) mounted on the active surface and configured to redistribute the electrical connectors from the plurality of semiconductor dies.
